(19) United States
(12) Patent Application Publication
(10) Pub. No.: US 2013/0164472 A1
(43) Pub. Date: Jun. 27, 2013

(54) HOUSING AND METHOD FOR MAKING THE SAME

(71) Applicants: XU LIU, Shenzhen City (CN); DA-HUA CAO, Shenzhen City (CN)

(72) Inventors: XU LIU, Shenzhen City (CN); DA-HUA CAO, Shenzhen City (CN)

(73) Assignees: FIH (HONG KONG) LIMITED, Kowloon (HK); SHENZHEN FUTAIHONG PRECISION INDUSTRY CO., LTD., ShenZhen City (CN)

(21) Appl. No.: 13/451,084

(22) Filed: Apr. 19, 2012

(30) Foreign Application Priority Data
Dec. 21, 2011 (CN) 201110432516.X

(51) Int. Cl. B32B 15/082; C23C 16/06; B32B 15/08; B05D 5/06

(52) U.S. Cl. 428/35.9; 427/258; 427/250; 428/34.1

(57) ABSTRACT

A housing includes a transparent substrate, a first ink layer formed on a surface of the substrate, and a metallic layer formed on the first ink layer. The first ink layer is at least translucent. The density of the first ink layer is gradually changed on the substrate. A method for making the housing is also described.

### BACKGROUND

1. Technical Field

The present disclosure relates to a housing and a method for making the housing.

2. Description of Related Art

Housings of electronic devices are usually coated with decorative coatings to present attractive appearances. The decorative coatings may be formed by spraying paint or ink, non-conductive vacuum metallization, anodic treatment, or electroplating. However, these coatings cannot present a novel and consumer appealing appearances.

Therefore, there is room for improvement within the art.

### BRIEF DESCRIPTION OF THE FIGURE

Many aspects of the disclosure can be better understood with reference to the following figure. The components in the figure are not necessarily drawn to scale, the emphasis instead being placed upon clearly illustrating the principles of the disclosure. Moreover, in the drawing like reference numerals designate corresponding parts throughout the several views. Wherever possible, the same reference numbers are used throughout the drawings to refer to the same or like elements of an embodiment.

FIG. 1 is a cross-sectional view of an exemplary embodiment of a housing.

FIG. 2 is a schematic view of a changing pattern of a first ink layer of the housing shown in FIG. 1.

FIG. 3 is a schematic view of forming the first ink layer shown in FIG. 1.

FIG. 4 is an overhead view of a deposition device.

### DETAILED DESCRIPTION

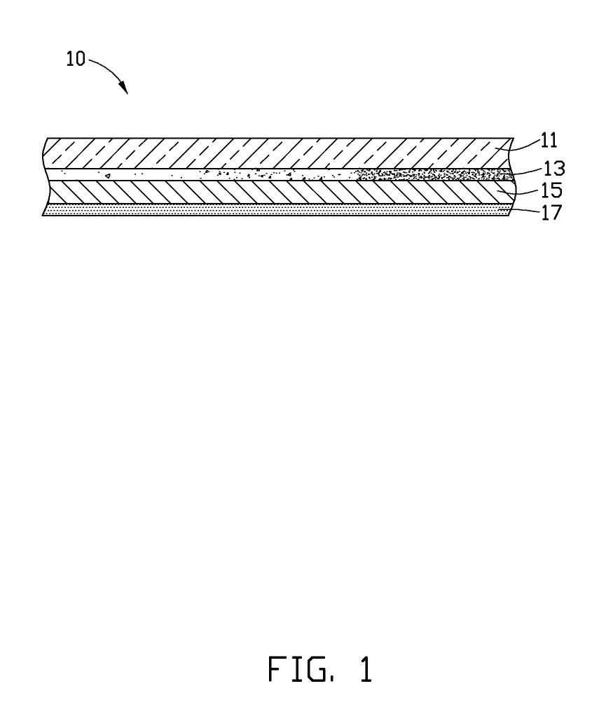

FIG. 1 shows a housing 10 according to an exemplary embodiment. The housing 10 includes a transparent substrate 11, a first ink layer 13 formed on a surface of the substrate 11, a metallic layer 15 formed on the first ink layer 13, and a second ink layer 17 formed on the metallic layer 15.

The substrate 11 may be made of transparent plastic. The plastic can be polycarbonate, or polymethyl methacrylate.

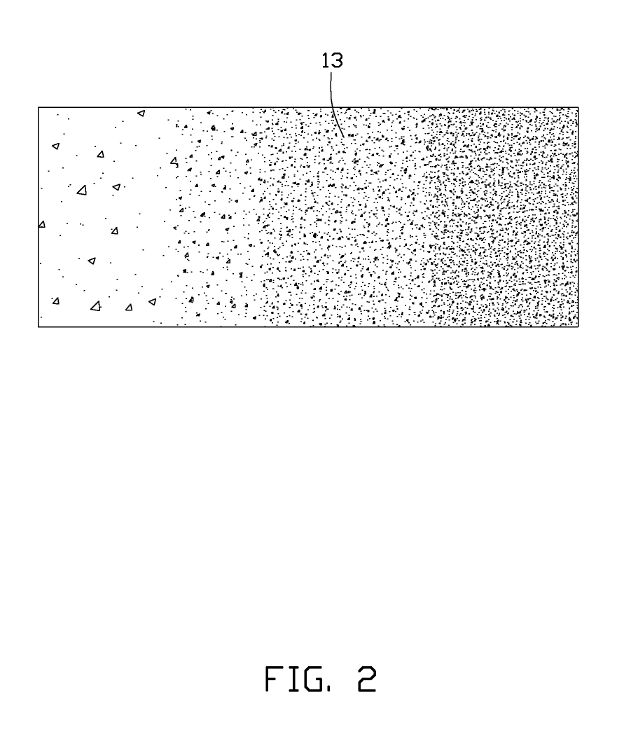

The first ink layer 13 can be a at least translucent ink layer formed by spraying ink. The first ink layer 13 contains acrylic urethane resins and particles. The particles may be silica gel. The first ink layer 13 can be colored with pigments. Referring to FIGS. 1 and 2, the density of the first ink layer 13 gradually changes from one end of the first ink layer 13 to the other end of the first ink layer 13 (e.g., longitudinal axis of the substrate 11). It is to be understood that, the density of the first ink layer 13 can also gradually change in any other regular or irregular pattern.

The metallic layer 15 may be made of aluminum, chromium, or silver, but is not restricted by the materials. The metallic layer 15 may have a thickness of about 0.5 μm to about 0.8 μm. The metallic layer 15 presents a metallic appearance.

Because the first ink layer 13 can be at least translucent, the metallic layer 15 can be observed from the surface of the substrate 11 opposite to the metallic layer 15. When observing from the surface of the substrate 11 opposite to the metallic layer 15, a deep, three-dimensional metallic appearance having a gradually-changed pattern will be presented, which is very novel and consumer appealing.

The second ink layer 17 is used to protect the metallic layer 15. The second ink layer 17 may have a dark color, which improves the reflection of light to enhance the metallic effect presented by the metallic layer 15.

A method for making the housing 10 may include the following steps:

The substrate 11 is provided.

The substrate 11 is ultrasonically cleaned using absolute ethyl alcohol for about 5 min-10 min.

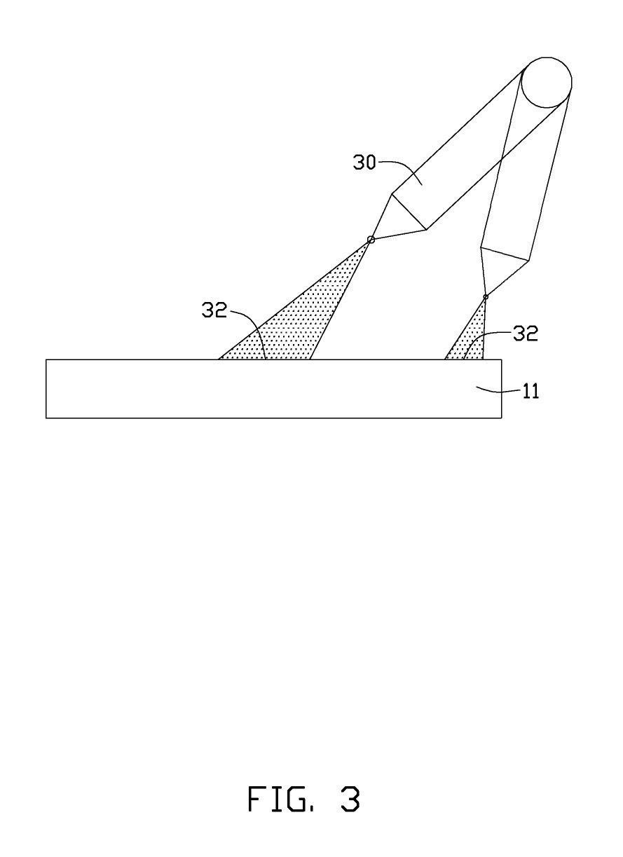

The first ink layer 13 is formed on a surface of the substrate 11. Referring to FIG. 3, a spraying device 30 is provided. During spraying, the spraying device 30 takes a pendulum movement on the substrate 11. Once passing a point of the locus of the pendulum movement, a spraying region 32 is defined. When the spraying device 30 moves to the high point of the pendulum movement, the straight line distance between the substrate 11 and the spraying device 30 is far, thus forms the low density region of the first ink layer 13. When the spraying device 30 moves to the low point, the straight line distance between the substrate 11 and the spraying device 30 is near, thus forms the high density region of the first ink layer 13. During the spraying process, the spraying device 30 may have a spraying pressure of about 0.1 MPa to about 0.6 MPa, and a move frequency of about 5 Hz to about 50 Hz.

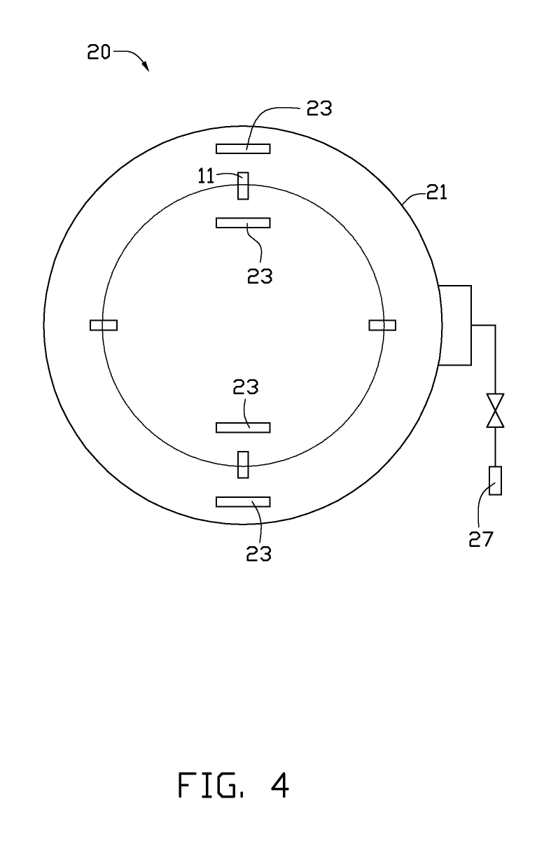

The metallic layer 15 is formed on the first ink layer 13 by a physical vapor deposition. Referring to FIG. 4, the substrate 11 having the first ink layer 13 may be positioned in a coating chamber 21 of a deposition device 20. The coating chamber 21 is fixed with targets 23 therein. The targets 23 may be made of aluminum, chromium, or silver. The coating chamber 21 is evacuated to about 8.0×10⁻³ Pa using a vacuum pump 27. Argon (Ar) gas having a purity of about 99.999% may be used as a working gas and is fed into the coating chamber 21 at a flow rate of about 100 standard-state cubic centimeters per minute (sccm) to about 300 sccm. A power of about 8 kilowatt (KW)-13 KW is applied to the targets 23, and then metal atoms are sputtered off from the targets 23 to deposit on the first ink layer 13 and form the metallic layer 15. During the depositing process, the substrate 11 may have a negative bias voltage of about −50 V to about −200 V. Depositing of the first ink layer 13 may take about 10 min to about 30 min.

The second ink layer 17 is formed on the metallic layer 15 by a ordinary spraying ink process.

It is believed that the exemplary embodiment and its advantages will be understood from the foregoing description, and it will be apparent that various changes may be made thereto without departing from the spirit and scope of the disclosure or sacrificing all of its advantages, the examples hereinbefore described merely being preferred or exemplary embodiment of the disclosure.

1. A housing, comprising:
a transparent substrate;
a first ink layer formed on a surface of the substrate, the first ink layer being at least translucent, the density of the first ink layer gradually changing along the longitudinal axis of the substrate; and
a metallic layer formed on the first ink layer.

2. The housing as claimed in claim 1, wherein the first ink layer contains acrylic urethane resins and silica gel particles.

3. The housing as claimed in claim 1, wherein the density of the first ink layer gradually changes from one end of the first ink layer to the other end of the first ink layer.

4. The housing as claimed in claim 1, wherein the first ink layer is colored with pigments.

5. The housing as claimed in claim 1, wherein the metallic layer is made of aluminum, chromium, or silver.

6. The housing as claimed in claim 1, wherein the metallic layer has a thickness of about 0.5 μm-0.8 μm.

7. The housing as claimed in claim 1, further comprising a second ink layer formed on the metallic layer.

8. The housing as claimed in claim 1, wherein the substrate is made of transparent plastic.

9. The housing as claimed in claim 8, wherein the plastic is polycarbonate or polymethyl methacrylate.

10. A method for making a housing, comprising:
providing a transparent substrate;
forming a first ink layer on a surface of the substrate, the first ink layer being at least translucent, the density of the first ink layer gradually changing along the longitudinal axis of the substrate; and
forming a metallic layer on the first ink layer using a physical vapor deposition process.

11. The method as claimed in claim 10, wherein forming the first ink layer is carried out using a spraying device, the spraying device moves like a pendulum relative to the substrate during spraying.

12. The method as claimed in claim 11, wherein during spraying, the spraying device has a spraying pressure of about 0.1 MPa-0.6 MPa, and a move frequency of about 5 Hz-50 Hz.

13. The method as claimed in claim 10, wherein forming the metallic layer is carried out in a coating chamber of a deposition device, uses argon as a working gas, the argon has a flow rate of about 100 sccm-300 sccm; uses a target made of aluminum, chromium, or silver, the target is applied with a power of about 8 KW-13 KW; forming the metallic layer takes about 10 min-30 min.

14. The method as claimed in claim 13, wherein the substrate has a negative bias voltage of about −50V to about −200V during forming the metallic layer.

15. The method as claimed in claim 10, further comprising a step of forming a second ink layer on the metallic layer.

16. The method as claimed in claim 10, further comprising, before forming the first ink layer, a step of ultrasonically cleaning the substrate using absolute ethyl alcohol for about 5 min-10 min.

17. The method as claimed in claim 10, wherein the metallic layer has a thickness of about 0.5 μm-0.8 μm.

18. The method as claimed in claim 10, wherein the first ink layer contains acrylic urethane resins and silica gel particles.

19. The method as claimed in claim 10, wherein the substrate is made of transparent plastic.

20. The method as claimed in claim 19, wherein the plastic is polycarbonate or polymethyl methacrylate.
